(19) United States
(12) Patent Application Publication
(10) Pub. No.: US 2007/0266277 A1
(43) Pub. Date: Nov. 15, 2007

(54) Memory diagnostic method

(75) Inventor: Maoko Oyamada, Kawasaki (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 11/820,618

(22) Filed: Jun. 20, 2007

Related U.S. Application Data
(63) Continuation of application No. PCT/JP04/19600, filed on Dec. 28, 2004.

(51) Int. Cl. G11C 29/00

(52) U.S. Cl. 714/718

(57) ABSTRACT

A storage device can reduce time for diagnosis and allows the diagnosis to be conducted on the entire area of a memory. The storage device includes a temporary memory that temporarily stores for a storage medium, data written to and/or read from a host system by the storage medium; a memory manager that manages writing and/or reading performed on the temporary memory; a first storage memory that complements a difference in processing speed of writing and/or reading between the host system and the temporary memory; and a second storage memory that complements a difference in processing speed of writing and reading between the storage medium and the temporary memory. The memory manager has a comparator, which compares the diagnostic data stored in the first storage memory with the read data stored in the second storage memory, and determines that there is an abnormality if a comparison result is inconsistent.

### CROSS REFERENCE TO RELATED APPLICATIONS

This application is a continuation of International Application No. PCT/JP2004/19600, filed on Dec. 28, 2004, now pending, herein incorporated by reference.

### TECHNICAL FIELD

The present invention relates to a storage device having a memory diagnostic function, and a memory diagnostic method in the storage device.

### BACKGROUND ART

At the present day, the information processors such as computers are equipped with various types of memories. Diagnosis is conducted on these memories to determine whether data can be written, held and read properly. As one such diagnostic method, there is the technology described in Japanese Unexamined Patent Publication No. H7-271679 wherein the right to possess a bus for accessing a memory is passed from a microprocessor to a diagnosis start/stop circuit every time diagnosis is performed on one address, to reduce the occupation of the microprocessor.

As such memory, there is an SDRAM which is equipped in a hard disk device to temporarily accumulate data exchanged between a host computer and a disk. Diagnosis is also conducted on this SDRAM disposed between the disk and the host computer, to determine whether the data can be written, held and read properly when the hard disk device is activated.

FIG. 1 shows a configuration of a hard disk device, host computer, and SDRAM disposed therebetween. Here, a host computer 6 writes and reads data to and from a storage medium 7. An SDRAM 2 exists therebetween and temporarily accumulates write data and read data. Here, the storage medium 7 is a magnetic disk and has a magnetic head assembly and the like required for accessing the data. Also, a first storage memory 4 is a mechanism for complementing the difference in speed of writing and reading between the host computer 6 and the SDRAM 2 (FIFO). A second storage memory 5 is a mechanism for complementing the difference in speed of writing and reading between the storage medium 7 and the SDRAM 2 (FIFO). A memory manager 1 is hardware for managing writing and reading performed on the SDRAM 2. A microprocessor 3 manages the entire hard disk device and activates or stops a spindle motor.

FIG. 2 shows an operation flow starting from activation of the hard disk device to the stage where the hard disk device reaches an available state. In step S1, the microprocessor 3 starts to operate after the power is turned on. Next, in step S2 the first storage memory 4, the second storage memory 5 and the SDRAM 2 are initialized. Thereafter, in step S3 initial diagnosis is conducted on the SDRAM 2. Furthermore, in step S4 initialization and the like of the microprocessor 3, a servo controller register and the like are performed. Finally, in step S5 the spindle motor is activated and the disk starts rotating steadily. After these steps, the hard disk device is brought into the available state.

At this moment, firmware is associated in some way with all of the steps, thus the plurality of steps are not executed in parallel.

Here, the detail of conventional initial diagnosis that is performed on the SDRAM 2 disposed between the hard disk device and the host computer 6 is described with reference to FIG. 1. This initial diagnosis is conducted using the microprocessor 3.

The microprocessor 3 generates 2 bytes of diagnostic data and transmits the diagnostic data to the memory manager 1 that manages writing and reading performed on the SDRAM 2. The memory manager 1 receives the diagnostic data from the microprocessor 3 and writes the diagnostic data on an address of the SDRAM 2 that is specified by the microprocessor 3. The memory manager 1 then reads the data from the address to which the data was previously written. The data that has been read by the memory manager 1 is transmitted from the memory manager 1 to the microprocessor 3, and the written data is compared with the read data in the microprocessor 3.

In order to perform the abovementioned comparison in all memory areas, 2 bytes of diagnostic data need to be written and read in each memory area, since the diagnostic data is 2 bytes. A RAS (Row Address Strobe), which is a signal for transmitting the timing for providing a row address, or a CAS (Column Address Strobe), which is a signal for transmitting the timing for providing a column address, needs to be waited every time the 2 bytes of data are written or read, thus a long time is required. Due to limitations of time required for the hard disk device to reach the available state, it was impossible to conduct diagnosis on all memory areas, thus the memory areas were divided, whereby the diagnosis was conducted only on some memory areas.

In the above method, reading and writing 2 bytes of diagnostic data are performed on each memory area on the basis of the firmware in which the memory diagnosis is implemented by the microprocessor, thus the processing speed of the memory diagnosis is slow. Moreover, since the diagnosis is conducted only on some of the memory areas, this memory diagnosis is less reliable than the case where the diagnosis is conducted on all memory areas.

### DISCLOSURE OF THE INVENTION

An object of the present invention, therefore, is to write and read massive amounts of data at once by using hardware and thereby increase the speed of memory diagnosis that was conventionally performed by a microprocessor on the basis of firmware, and to perform other processes in parallel with the memory diagnosis by sharing the microprocessor. In addition to this object, another object of the present invention is to improve the reliability of memory diagnosis by conducting diagnosis on the entire memory area.

In order to achieve the above objects, according to a first aspect of the present invention, there is provided a storage device with a memory diagnostic function, having: a storage medium to and from which data can be read and written by a host computer; an SDRAM that temporarily accumulates data written and read to and from the storage medium; a memory manager that manages writing and reading performed on the SDRAM; a first storage memory that complements a difference in processing speed of writing and reading between the host computer and the SDRAM; and a second storage memory that complements a difference in processing speed of writing and reading between the storage medium and the SDRAM, wherein the memory manager has a comparator, writes diagnostic data held in the first storage memory into the SDRAM, reads the written data from the SDRAM, and stores the read data into the second storage memory, and the comparator compares the diagnostic data stored in the first storage memory with the read data stored in the second storage memory, and notifies of an abnormality if a comparison result is inconsistent.

According to a second aspect of the present invention, there is provided a diagnostic method for diagnosing an SDRAM of a storage device having: a storage medium to and from which data can be written and read by a host computer; an SDRAM that temporarily accumulates data written and read to and from the storage medium; a memory manager that manages writing and reading performed on the SDRAM; a first storage memory that complements a difference in processing speed of writing and reading between the host computer and the SDRAM; and a second storage memory that complements a difference in processing speed of writing and reading between the storage medium and the SDRAM, the method having the steps of: writing diagnostic data stored in the first storage memory into the SDRAM; reading the written data from the SDRAM and storing the data into the second storage memory; and using a comparator within the memory manager to compare the diagnostic data stored in the first storage memory with the read data stored in the second storage memory, and notify of an abnormality if a comparison result is inconsistent.

According to a third aspect of the present invention, there is provided a storage device with a memory diagnostic function, having: a storage medium to and from which data can be written and read by a host computer; an SDRAM that performs temporal accumulation when data is written and read to and from the storage medium; a memory manager that manages writing and reading performed on the SDRAM; a first storage memory that complements a difference in processing speed of writing and reading between the host computer and the SDRAM; and a second storage memory that complements a difference in processing speed of writing and reading between the storage medium and the SDRAM, wherein: the memory manager has a cyclic redundancy code calculator for calculating cyclic redundancy codes and a comparator for comparing the cyclic redundancy codes, writes, to the SDRAM, write data that is generated based on predetermined diagnostic data that is set beforehand in the first storage memory, and reads the write data from the SDRAM; and the cyclic redundancy code calculator calculates cyclic redundancy codes based on the write data when the write data is written to the SDRAM, and writes the write data and the calculated cyclic redundancy codes to the SDRAM. The cyclic redundancy code calculator then calculates cyclic redundancy codes based on the read data. The comparator compares the cyclic redundancy codes based on the write data with the cyclic redundancy codes based on the read data, and notifies of an abnormality if a comparison result is inconsistent.

According to the third aspect of the present invention, in a more preferred embodiment, the memory manager calculates seeds that are increased or reduced by a predetermined amount every time the write data is written or the read data is read, and the cyclic redundancy code calculator adds the calculated seeds to the write data or read data and thereby obtains a different cyclic redundancy code from the same write data or read data.

According to the third aspect of the present invention, in a further preferred embodiment, the write data is configured from a plurality of the diagnostic data items.

Moreover, according to a fourth aspect of the present invention, there is provided a diagnostic method for diagnosing an SDRAM of a storage device having: a storage medium to and from which data can be written and read by a host computer; an SDRAM that performs temporal accumulation when data is written and read to and from the storage medium; a memory manager that manages writing and reading performed on the SDRAM; a first storage memory that complements a difference in processing speed of writing and reading between the host computer and the SDRAM; and a second storage memory that complements a difference in processing speed of writing and reading between the storage medium and the SDRAM, the method having the steps in which: the memory manager writes, to the SDRAM, write data that is generated based on predetermined diagnostic data that is set beforehand in the first storage memory; a cyclic redundancy code calculator within the memory manager calculates cyclic redundancy codes based on the write data and writes the write data and the calculated cyclic redundancy codes to the SDRAM; the memory manager reads the written cyclic redundancy codes from the SDRAM; the memory manager reads the write data from the SDRAM; the cyclic redundancy code calculator within the memory manager calculates the cyclic redundancy codes based on the read data; and a comparator within the memory manager compares the cyclic redundancy codes based on the write data with the cyclic redundancy codes based on the read data, and notifies of an abnormality if a comparison result is inconsistent.

According to the fourth aspect of the present invention, in a preferred embodiment each of the storage memories is configured from a FIFO memory.

Also, according to the fourth aspect of the present invention, in a further preferred embodiment the memory manager calculates seeds that are increased or reduced by a predetermined amount every time the write data is written or the read data is read, and the cyclic redundancy code calculator adds the calculated seeds to the write data or read data and thereby obtains a different cyclic redundancy code from the same write data or read data.

Moreover, according to the fourth aspect of the present invention, in a further preferred embodiment the write data is configured from a plurality of the diagnostic data items.

According to the memory diagnostic function of the present invention, the diagnostic data stored in each storage memory is written to and read from the SDRAM by means of hardware, and is further compared with different diagnostic data, whereby the diagnosing time can be reduced and diagnosis can be conducted on all areas of the SDRAM. Also, memory diagnosis can be performed without occupying the microprocessor, thus memory diagnosis can be performed in parallel with other operations.

### BRIEF DESCRIPTION OF THE DRAWINGS

FIG. 1 shows configurations of a hard disk device, host computer, and SDRAM disposed therebetween;

FIG. 2 is an operation flow starting from activation of the hard disk device to the stage where the hard disk device reaches an available state;

FIG. 3 is a configuration diagram of the hard disk device having a memory diagnostic function of a first embodiment of the present invention;

FIG. 4 shows an arbitration mechanism for processing a request sent to a memory manager;

FIG. 5 is an operation flow of memory diagnosis according to the first embodiment of the present invention;

FIG. 6 is a configuration diagram of a hard disk device having a memory diagnostic function according to a second embodiment of the present invention;

FIG. 7 is an operation flow of memory diagnosis according to the second embodiment of the present invention;

FIG. 8 shows data that is written to the SDRAM according to the second embodiment of the present invention;

FIG. 9 is an explanatory diagram of a cyclic redundancy code; and

FIG. 10 shows an operation flow of a hard disk device having the memory diagnostic function of the present invention and an operation flow of a hard disk device without the memory diagnostic function of the present invention.

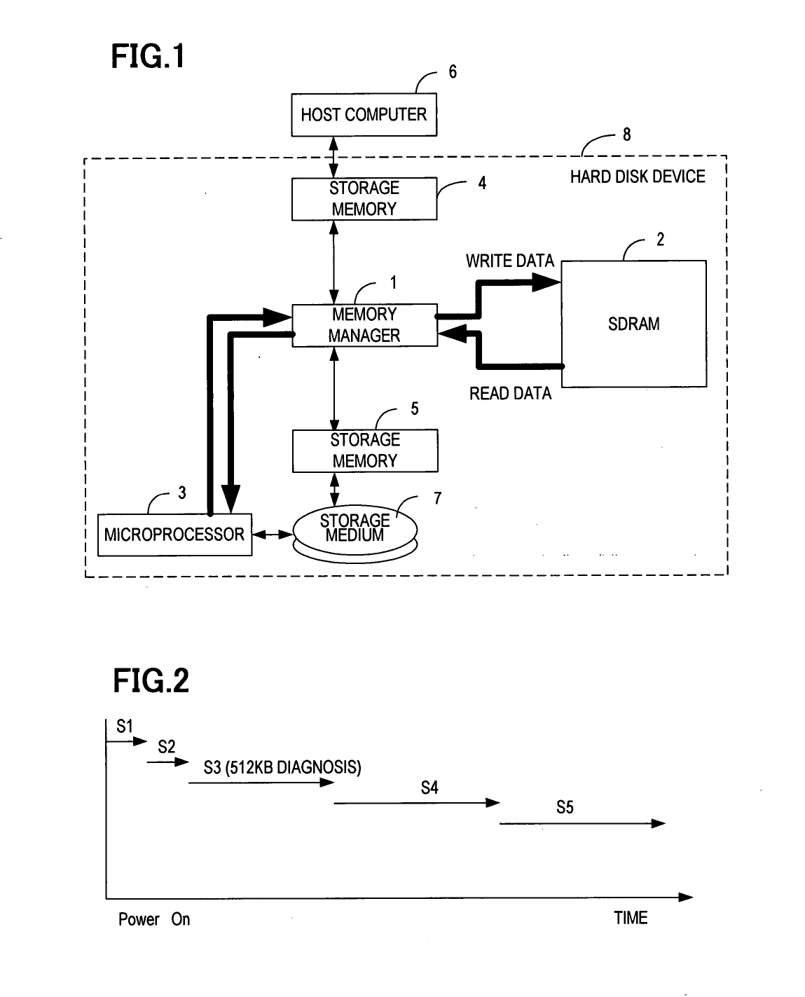

### BEST MODE FOR CARRYING OUT THE INVENTION

The embodiments of the present invention are described hereinafter with reference to the drawings. However, the technical scope of the present invention is not limited to these embodiments and thus covers the matters described in the patent claims and equivalents thereof.

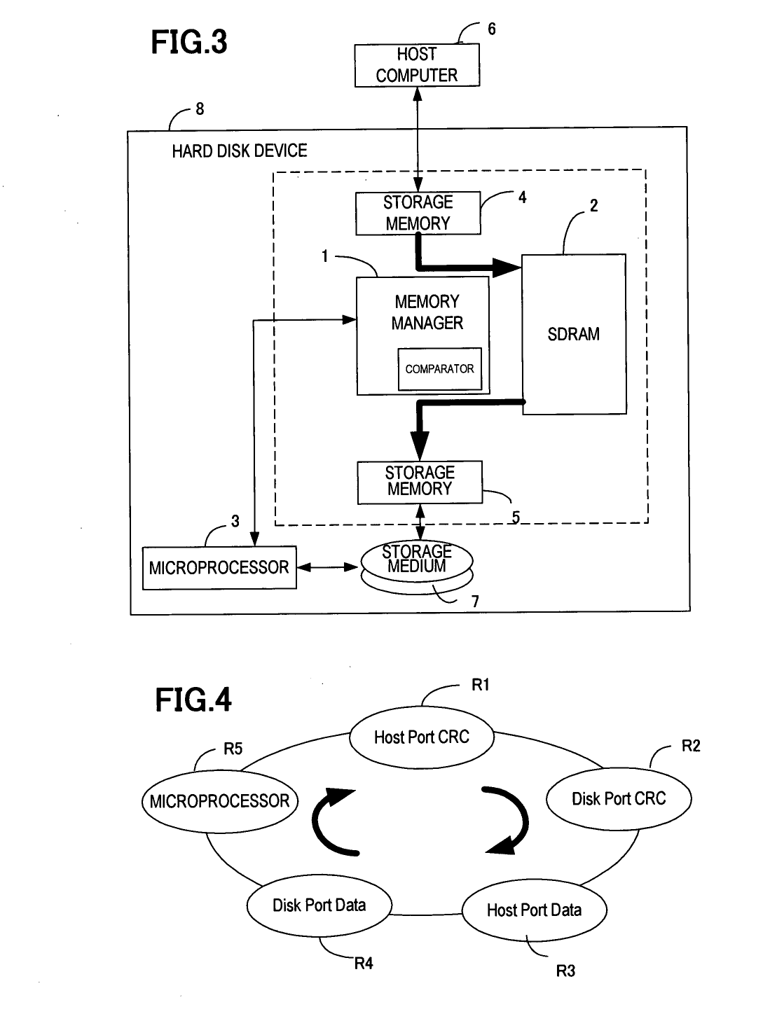

FIG. 3 is a configuration diagram of a hard disk device having a memory diagnostic function of a first embodiment of the present invention. A memory manager 1 for managing writing and reading of data to and from an SDRAM 2 is connected to a host computer 6, storage medium 7, and microprocessor 3 managing the entire hard disk device. A first storage memory 4 is disposed between the memory manager 1 and the host computer 6. A second storage memory 5 is disposed between the memory manager 1 and the storage medium 7. In the present embodiment the section surrounded by the dashed line shown in FIG. 3 is a memory diagnostic apparatus.

It should be noted in the first embodiment of the present invention that the first storage memory 4 and the second storage memory 5 are each configured from a FIFO. Normally, the hard disk device has: the SDRAM 2 for temporarily accumulating write data and read data; a FIFO for complementing a difference in data transfer speed between the storage medium 7 and the SDRAM 2; and a FIFO for complementing a difference in data transfer speed between the host computer 6 and the SDRAM 2. By configuring the memory diagnostic apparatus by means of these existing FIFOs, changes in a conventional circuit and the size of the memory diagnostic apparatus can be minimized.

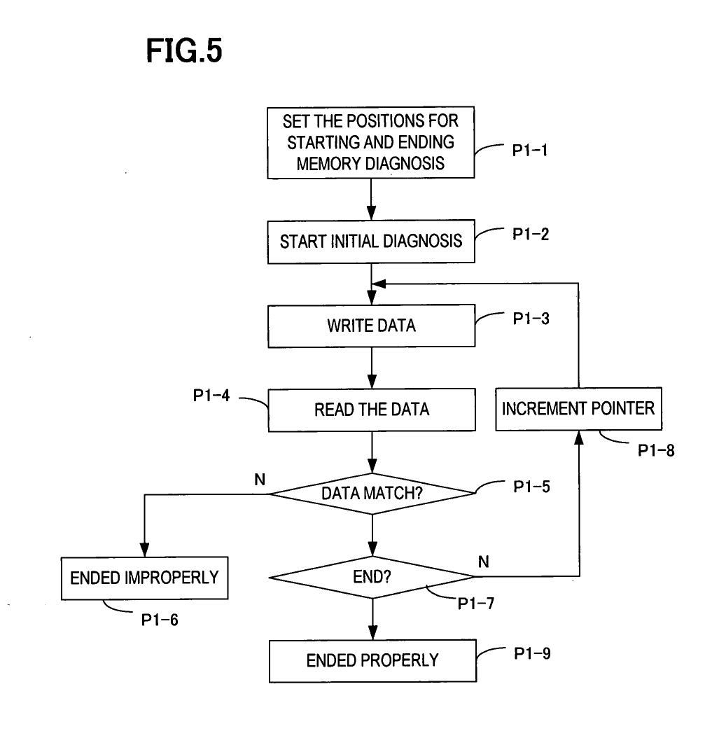

FIG. 4 shows an arbitration mechanism for processing a request sent to the memory manager 1. The memory manager 1 uses the arbitration mechanism to process various requests such as a request for reading or writing data from or to the SDRAM 2. As such requests to the memory manager 1, there are, for example: a request R1 for creating a cyclic redundancy code (CRC) from data stored in the first storage memory 4 and writing or reading the created cyclic redundancy code to or from the SDRAM 2; a request R2 for creating a cyclic redundancy code from data stored in the second storage memory 5 and writing or reading the created cyclic redundancy code to or from the SDRAM 2; a request R3 for writing and reading the data between the first storage memory 4 and the SDRAM 2; a request R4 for writing and reading the data between the second storage memory 5 and the SDRAM 2; and a request R5 for accessing the SDRAM 2 from the microprocessor 3.

The arbitration mechanism shown in FIG. 4 processes the generated requests clockwise. For example, when writing the data stored in the first storage memory 4 to the SDRAM 2, the request R3 is generated, and checking is performed in order of the request R4, request R5 and request R1 after the request R3 is processed. If no request is generated, the arbitration mechanism loops in an idle state.

When initial diagnosis is conducted on the SDRAM 2, diagnostic data is stored in the first storage memory 4. This data may be generated by the microprocessor 3 or transferred from the host computer 6. The diagnostic data is written to the SDRAM 2 via the memory manager 1 and immediately read by the memory manager 1. This read data is stored into the second storage memory 5. Then, a comparator of the memory manager 1 compares the data stored in the first storage memory 4 with the data stored in the second storage memory 5, whereby the diagnosis is conducted on the SDRAM 2.

FIG. 5 is an operation flow of the memory diagnosis according to the first embodiment of the present invention. First, the microprocessor 3 that is operated based on firmware determines positions for starting and ending the memory diagnosis (process step P1-1). The microprocessor 3 then activates an initial diagnostic function of the memory manager 1 (process step P1-2). The process step P1-1 and the process step P1-2 are realized by the firmware, and subsequent steps are realized by the hardware of the memory manager 1.

The memory manager 1 writes the diagnostic data stored in the first storage memory 4 to the SDRAM 2 (process step P1-3). At this moment, the request R3 is generated and processed in the arbitration mechanism shown in FIG. 4. Next, the memory manager 1 immediately reads the written data on an address and stores this data into the second storage memory 5 (process step P1-4). At this moment, the request R4 is generated and processed in the arbitration mechanism shown in FIG. 4. The comparator of the memory manager compares the data stored in the first storage memory 4 with the data stored in the second storage memory 5 (process step P1-5). If an inconsistency is detected between these compared data items, the comparator immediately determines that the comparison result is abnormal, and the diagnosis on the SDRAM 2 is ended (process step P1-6). If the comparison result is consistent, it is confirmed whether the position of a pointer is the end position or not (process step P1-7). If the position of the pointer is not the end position, the pointer of the SDRAM 2 is incremented (process step 1-8), and the process returns to the process step of writing the diagnostic data to the SDRAM 2 (process step P1-3). The loop from the process step P1-3 to the process step P1-8 is repeated until the pointer reaches the end position. Once the pointer reaches the end position, the memory diagnostic function is ended properly (process step P1-9).

If the SDRAM 2 has an 8-megabyte area and the size of the first storage memory 4 and of the second storage memory 5 is 128 bytes, the loop of writing, reading and comparing (the loop from the process step P1-3 to the process step P1-8) is executed no more than 65536 times in order to diagnose the entire area of the SDRAM 2. In the prior art, the loop of writing, reading and comparing needs to be executed four mega times for each 2-byte data in order to diagnose the entire area of the SDRAM 2, thus the present invention is a significantly improved technology. By reducing the number of loops, the overhead time required when writing, reading and comparing the data can be omitted, reducing the entire-time significantly.

In this manner, by writing and reading massive amounts of data at once by using hardware, the first embodiment of the present invention can increase the speed of memory diagnosis that was conventionally performed by the microprocessor 3 on the basis of the firmware, and can perform other processes in parallel with the memory diagnosis by sharing the microprocessor 3. As a result, the entire area of the SDRAM 2 can be diagnosed, whereby the reliability can be improved.

It should be noted in the first embodiment of the present invention that the example of the storage device is described using the hard disk device, but the present invention can be applied similarly to an apparatus or product having a memory.

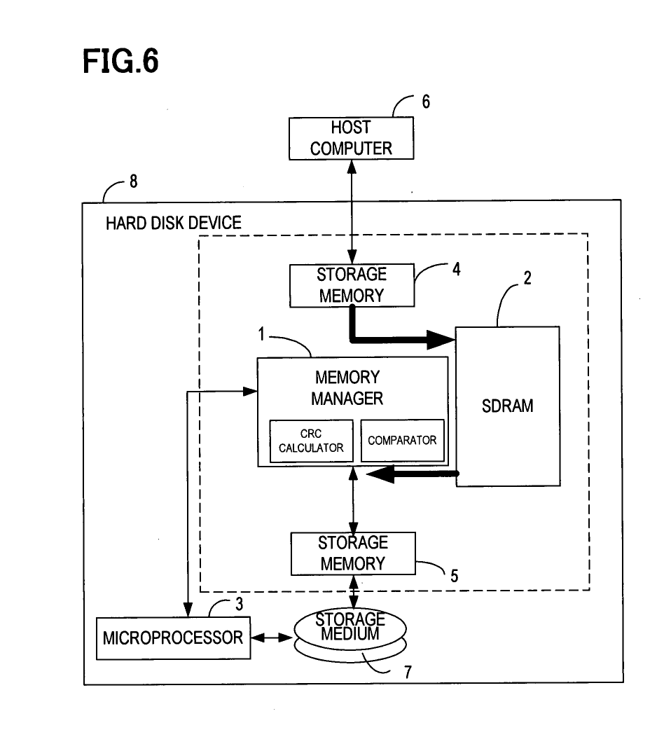

FIG. 6 is a configuration diagram of a hard disk device having a memory diagnostic function according to a second embodiment of the present invention. The memory manager 1 for managing writing and reading of data to and from the SDRAM 2 is connected to the host computer 6, storage medium 7, and microprocessor 3 managing the entire hard disk device. The first storage memory 4 is disposed between the memory manager 1 and the host computer 6, and the second storage memory 5 is disposed between the memory manager 1 and the storage medium 7. In the present embodiment the section surrounded by the dashed line shown in FIG. 6 is a memory diagnostic apparatus.

It should be noted in the second embodiment of the present invention that the first storage memory 4 and the second storage memory 5 are each configured from a FIFO. Normally, the hard disk device has: the SDRAM 2 for temporarily accumulating write data and read data; a FIFO for complementing a difference in data transfer speed between the storage medium 7 and the SDRAM 2; and a FIFO for complementing a difference in data transfer speed between the host computer 6 and the SDRAM 2. By configuring the memory diagnostic apparatus by means of these existing FIFOs, changes in a conventional circuit and the size of the memory diagnostic apparatus can be minimized.

Diagnostic data is stored in the first storage memory 4. This data may be generated by the microprocessor 3 or transferred from the host computer 6. The diagnostic data is repeatedly written to the SDRAM 2 via the memory manager 1 until a write end position is reached. At this moment, a cyclic redundancy code is calculated from a seed and 512 bytes of write data (the method of calculation is described hereinafter), and the cyclic redundancy code is written to a part of the SDRAM 2. It should be noted that the seed is 4-byte data that is initialized to 0 when the initial diagnosis is started, and incremented every time 512-byte diagnostic data is written from the starting position. Also, the amount of one sector on the SDRAM 2 is 512 bytes, thus when the amount of the first storage memory 4 and of the second storage memory 5 is 128 bytes, the data is transferred four times when writing and reading is performed with respect to the SDRAM 2.

Thereafter, the memory manager 1 reads one sector of data and a relevant cyclic redundancy code from the write starting position, and calculates cyclic redundancy codes again from the read data of one sector. The comparator of the memory manager 1 compares the read cyclic redundancy code with the calculated cyclic redundancy codes, whereby the diagnosis on the SDRAM 2 is ended.

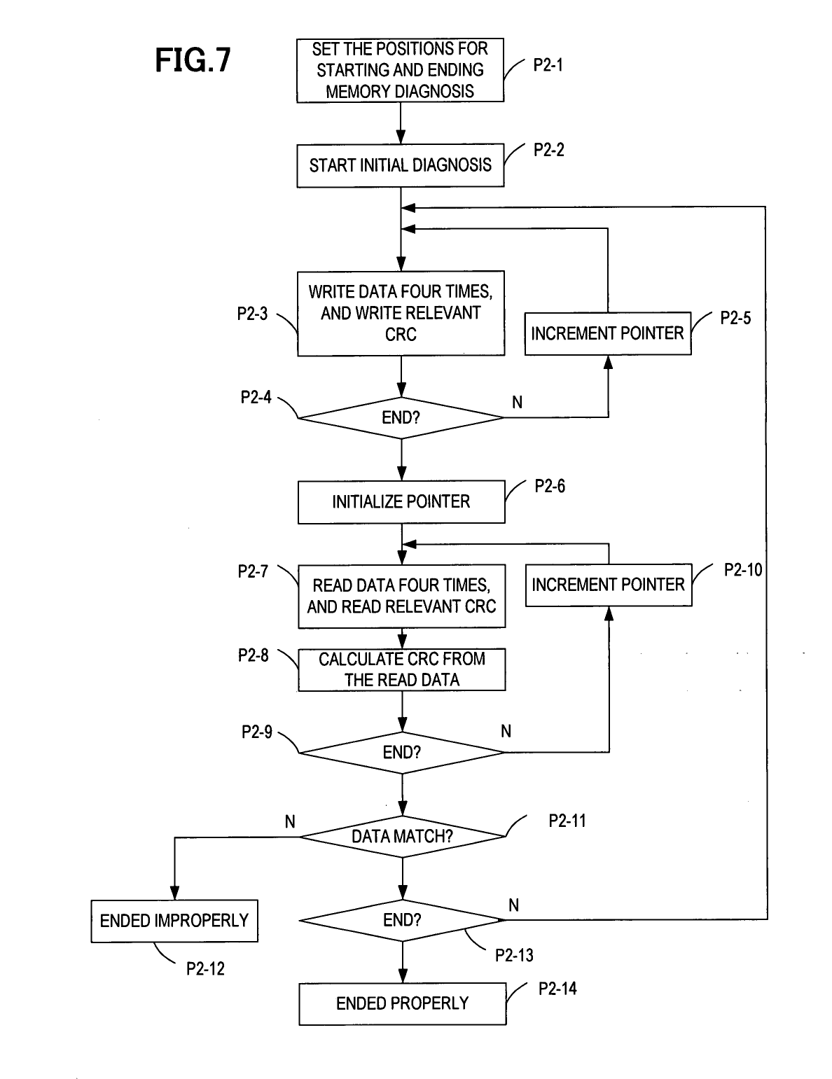

FIG. 7 is an operation flow of memory diagnosis according to the second embodiment of the present invention. First, the microprocessor 3 that is operated based on the firmware determines positions for starting and ending the memory diagnosis (process step P2-1). The microprocessor 3 then activates an initial diagnostic function of the memory manager 1 (process step P2-2). The process step P2-1 and the process step P2-2 are realized by the firmware, and subsequent steps are realized by the hardware of the memory manager 1.

The memory manager 1 sequentially writes the diagnostic data stored in the first storage memory 4 to the SDRAM 2 (process step P2-3) while incrementing the pointer (process step P2-5). At this moment, the request R3 for performing writing from the first storage memory 4 to the SDRAM 2 is generated in the arbitration mechanism shown in FIG. 4. The cyclic redundancy code calculator of the memory manager 1 calculates cyclic redundancy codes from one sector of write data and relevant seed, and sequentially writes the cyclic redundancy codes to the starting position of the SDRAM 2. At this moment, the request R3 is generated four times and the request R1 is generated once at the end in the arbitration mechanism. When it is confirmed that the end position that is initially set by the microprocessor 3 is reached (process step P2-4), writing is stopped and the pointer is initialized (process step P2-6).

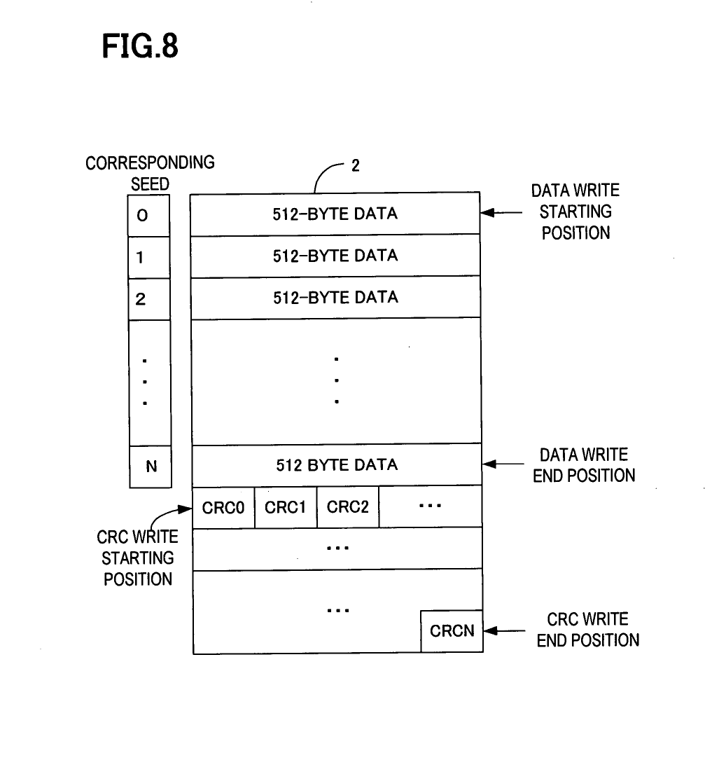

FIG. 8 shows data that is written to the SDRAM 2 according to the second embodiment of the present invention. The 128 bytes of diagnostic data stored in the first storage memory 4 is sequentially written from the memory diagnosis starting position determined in the process step P2-1 (a data write starting position shown in FIG. 8), the writing being performed four times, whereby one sector of 512 bytes is formed. The seed is incremented every time data of one sector is written, and the cyclic redundancy code combined with the data of one sector is calculated. Then, corresponding cyclic redundancy codes are sequentially written from a position that is planned to be the data write end position. The diagnostic data eventually reaches the data write end position, and relevant redundancy codes reach a CRC write end position.

Next, the process returns to FIG. 7, wherein the initial diagnostic function of the memory manager 1 reads the written data and cyclic redundancy codes (process step P2-7) while incrementing the pointer (process step P2-10). At this moment, the request R4 for reading the data from the SDRAM 2 to the second storage memory 5 is generated four times in the arbitration mechanism, and at the end the request R2 for reading the cyclic redundancy codes is generated. Here, the cyclic redundancy codes are sent to the comparator of the memory manager 1. The cyclic redundancy code calculator of the memory manager 1 calculates cyclic redundancy codes from the read data and relevant seed (process step P2-8), and sends the calculated cyclic redundancy codes to the comparator.

Two of the cyclic redundancy codes that are sent from the comparator are compared with each other (process step P2-11), and if the two cyclic redundancy codes match, it is confirmed whether the microprocessor 3 has reached the end position (process step P2-13). If the two cyclic redundancy codes do not match, the initial diagnostic function of the memory manager 1 detects an abnormality and is ended (process step P2-12).

Finally, when it is confirmed that the diagnosis on the entire area of the SDRAM is finished and that the microprocessor 3 is in the end position, if it is determined that the microprocessor 3 is not in the end position, the data and cyclic redundancy codes are read from the SDRAM 2 again, and this reading is repeated. If it is determined that the microprocessor 3 is in the end position, the initial diagnostic function of the memory manager 1 is ended properly (process step P2-14).

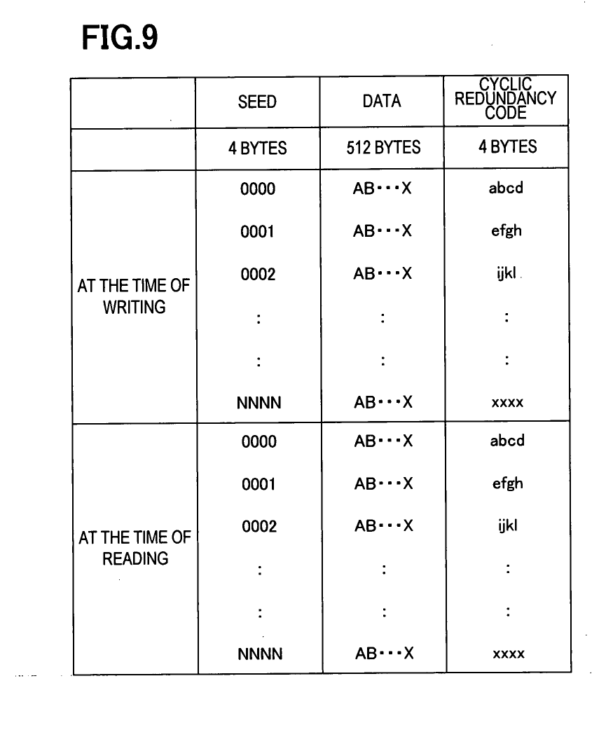

FIG. 9 is an explanatory diagram of a cyclic redundancy code. 128 bytes of the diagnostic data are not changed, thus the same data (AB . . . X in FIG. 9) is repeatedly written from the first storage memory 4 to the SDRAM 2. A 4-byte seed is incremented once, while the 128-byte diagnostic data is written four times. By dividing 516 bytes of data by a certain constant, the 516-byte data being obtained by adding the seed to the 512 bytes of data, 4-byte cyclic redundancy code is obtained. The memory manager 1 does not have to secure the 516-byte area for this division, thus 132 bytes of data, which is obtained by adding the 4-byte seed and the 128-byte diagnostic data, is divided by a certain constant. Further, the 132-byte data that is obtained by adding the remainder of the above division and the diagnostic data is divided by a certain constant again. In this manner, the remainders obtained by repeating such division four times are the cyclic redundancy codes. As shown in FIG. 9, since the seed is incremented for each sector, different cyclic redundancy codes (abcd, efgh, and the like) are obtained for the same 512-byte data such as AB . . . X.

It is efficient that the comparator of the memory manager 1 compares the 4-byte cyclic redundancy code with respect to the diagnosis performed on the 512-byte area. The amount of comparison is 1/128 in the case of comparing the 4-byte cyclic redundancy code, compared to the case where the 521-byte data is directly compared. Also, it is no longer necessary to hold the 512-byte data that is read from the SDRAM 2.

The case where the diagnostic data for 100 sectors and cyclic redundancy codes corresponding to the diagnostic data are written from the first storage memory 4 to the SDRAM 2 is described along with the operation of the arbitration mechanism. The arbitration mechanism is started simultaneously with the initial diagnostic function, and when no request is generated, the arbitration mechanism loops in an idle state as shown in FIG. 4. Here, the request R3 for writing data from the first storage memory 4 to the SDRAM 2 is generated. After 128 bytes of diagnostic data is written from the first storage memory 4, the request R3 that is generated again is processed since the requests R1, R2, R4 and R5 are not generated. The request R3 is generated four times until the processing of one 512-byte sector is ended. After the request R3 is processed four times, the request R1 for generating and writing a cyclic redundancy code is generated, whereby a cyclic redundancy code for the written 512-byte data is generated and written. Thereafter, diagnostic data for 100 sectors and-cyclic redundancy codes corresponding to the diagnostic data are written by repeating, total of 100 times, four processes on the request R3 and one process on the request R1.

Next, reading of the written diagnostic data of 100 sectors and comparison of the cyclic redundancy codes corresponding to the diagnostic data are described along with the operation of the arbitration mechanism. After writing the 100 sectors of data is finished, the pointer and seed are initialized, and reading of the data and cyclic redundancy codes is started. In the arbitration mechanism the request R4 for reading the data from the SDRAM 2 to the second storage memory 5 is generated, and the reading is repeated four times so that one sector of the data is processed. At this moment, cyclic redundancy codes corresponding to the data that is read four times and the seed are calculated. Thereafter, the request R1 for reading the cyclic redundancy codes written to the SDRAM 2 is generated and processed. Two of the cyclic redundancy codes are compared with each other, and if these cyclic redundancy codes do not match, an abnormality is detected and the diagnosis is ended. The above-described operation is repeated 100 times to read the 100 sectors of data, whereby the initial diagnostic function is ended properly.

In this manner, in the second embodiment of the present invention, the speed of the memory diagnosis can be increased by diagnosing the memory by means of the hardware and writing and reading relatively large data at once. Accordingly, the entire area of the SDRAM 2 can be diagnosed, whereby the reliability can be improved. Furthermore, the memory diagnosis that was performed using the microprocessor on the basis of the conventional firmware is performed using hardware, whereby the microprocessor can be shared to perform other processes.

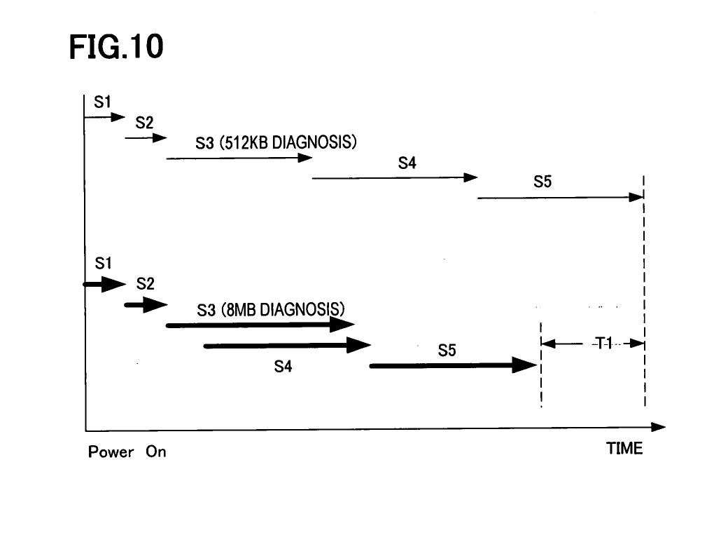

FIG. 10 shows an operation flow of the hard disk device having the memory diagnostic function of the present invention and an initial operation sequence of a conventional hard disk device without the memory diagnostic function of the present invention. The thick arrow shown on the lower side of the figure is the initial operation sequence of the hard disk device having the memory diagnostic function of the present invention, and the thin arrow on the upper side shows the operation flow of the hard disk device without the memory diagnostic function of the present invention.

There is no difference between the step S1 for executing the firmware in the microprocessor 3 and the step S2 for initializing the first storage memory 4, second storage memory 5 and SDRAM 2. However, in the step S3 for conducting the initial diagnosis on the SDRAM 2, the initial diagnosis is completed faster by using the hard disk device that is not provided with the memory diagnostic function of the present invention. This is because the memory diagnostic function of the present invention conducts diagnosis on 8 MB memory at 330 ms, while the conventional technology conducts diagnosis on 512 KB memory at 250 ms. However, in the memory diagnostic function of the present invention, the microprocessor 3 is not occupied, thus the process can proceed to step S4 where the firmware executed on the microprocessor 3 and the servo controller are initialized, without waiting for the step S3 to be completed. In the conventional memory diagnostic function, the process proceeds to the step S4 after the step S3 is ended. Step S5 for activating the spindle motor can be applied to both memory diagnostic function of the present invention and that of the conventional technology, but a time difference of T1 can be saved eventually in the present invention.

In this manner, by applying the memory diagnostic function of the present invention to a hard disk device, the time between when the power is activated and when the available state is reached can be reduced, whereby diagnosis can be conducted on the entire memory area.

It should be noted that the second embodiment of the present invention is described using an example of applying the memory diagnostic function of the present invention to the SDRAM of the hard disk device, but the memory diagnostic function of the present invention can also be applied to a generally-used memory.

Moreover, although the second embodiment of the present invention is described using a hard disk device as an example of the storage device, the present invention can be applied to a generally-used apparatus or a product that has, between such apparatus or product and the host system, a memory functioning as a buffer memory or cache memory for temporarily accumulating data, or to apparatuses or systems that use removable storage media including magnetic tape units, optical disk units and magneto optical disk drives.

Although a personal computer or a host computer is described as the host system, the host system corresponds to a host processor (CPU or the like) in the case of a product equipped with a storage device such as a hard disk video recorder, of corresponds to a host system that performs data transfer control on the storage device.

### INDUSTRIAL APPLICABILITY

As described above with reference to the drawings, the present invention provides the storage device that has a memory diagnostic function for reducing the time for diagnosis and allowing the diagnosis to be conducted on the entire area of the SDRAM by writing and reading the diagnostic data stored in the storage memory to and from the SDRAM by means of hardware, and further comparing these diagnostic data items. Furthermore, the storage device having this memory diagnostic function can perform memory diagnosis without occupying the microprocessor, thus other operations can be performed in parallel with the memory diagnosis.

1. A storage device with a memory diagnostic function, comprising:
a temporary memory that temporarily stores for a storage medium, data written to and/or read from a host system by the storage medium;
a memory manager that manages writing and/or reading performed on the temporary memory;
a first storage memory that complements a difference in processing speed of writing and/or reading between the host system and the temporary memory; and
a second storage memory that complements a difference in processing speed of writing and reading between the storage medium and the temporary memory,
wherein the memory manager has a comparator, writes diagnostic data held in the first storage memory into the temporary memory, reads the written data from the temporary memory, and stores the read data into the second storage memory,
and the comparator compares the diagnostic data stored in the first storage memory with the read data stored in the second storage memory, and determines that there is an abnormality if a comparison result is inconsistent.

2. The storage device with a memory diagnostic function according to claim 1, wherein the first storage memory and the second storage memory are each comprised of a FIFO memory.

3. A memory diagnostic method for diagnosing a temporary memory of a storage device with a memory diagnostic function, having: a temporary memory that temporarily stores for a storage medium, data written to and/or read from a host system by the storage medium; a memory manager that manages writing and/or reading performed on the temporary memory; a first storage memory that complements a difference in processing speed of writing and/or reading between the host system and the temporary memory
the method comprising the steps of:
writing diagnostic data stored in the first storage memory into the temporary memory;
reading the written data from the temporary memory and storing the data into the second storage memory; and
using a comparator within the memory manager to compare the diagnostic data stored in the first storage memory with the read data stored in the second storage memory, and determine that there is an abnormality if a comparison result is inconsistent.

4. A storage device with a memory diagnostic function, comprising:
a temporary memory that temporarily stores for a storage medium, data written to and/or read from a host system by the storage medium;
a memory manager that manages writing and/or reading performed on the temporary memory;
a first storage memory that complements a difference in processing speed of writing and/or reading between the host system and the temporary memory; and
a second storage memory that complements a difference in processing speed of writing and reading between the storage medium and the temporary memory,
wherein the memory manager has a cyclic redundancy code calculator for calculating cyclic redundancy codes and a comparator for comparing the cyclic redundancy codes, writes, to the temporary memory, write data that is generated based on predetermined diagnostic data that is set beforehand in the first storage memory, and reads the write data from the temporary memory,
the cyclic redundancy code calculator calculates cyclic redundancy codes based on the write data when the write data is written to the temporary memory, writes the write data and the calculated cyclic redundancy codes to the temporary memory, and calculates cyclic redundancy codes based on the read data, and
the comparator compares the cyclic redundancy codes based on the write data with the cyclic redundancy codes based on the read data, and determines that there is an abnormality if a comparison result is inconsistent.

5. The storage device with a memory diagnostic function according to claim 4, wherein the first storage memory and the second storage memory are each comprised of a FIFO memory.

6. The storage device with a memory diagnostic function according to claim 4, wherein the memory manager calculates seeds that are increased or reduced by a predetermined amount every time the write data is written or the read data is read, and the cyclic redundancy code calculator adds the calculated seeds to the write data or read data and thereby obtains a different cyclic redundancy code from the same write data or read data.

7. The storage device with a memory diagnostic function according to claim 4, wherein the write data comprises a plurality of the diagnostic data items.

8. A memory diagnostic method for diagnosing a temporary memory of a storage device with a memory diagnostic function, having: a temporary memory that temporarily stores for a storage medium, data written to and/or read from a host system by the storage medium; a memory manager that manages writing and/or reading performed on the temporary memory; a first storage memory that complements a difference in processing speed of writing and/or reading between the host system and the temporary memory
the method comprising the steps of:
by the memory manager, writing to the temporary memory, write data that is generated based on predetermined diagnostic data that is set beforehand in the first storage memory;
by a cyclic redundancy code calculator within the memory manager, calculating cyclic redundancy codes based on the write data and writings the write data and the calculated cyclic redundancy codes to the temporary memory;
by the memory manager, reading the written cyclic redundancy codes from the temporary memory, and reading the write data from the temporary memory;
by the cyclic redundancy code calculator within the memory manager, then calculating cyclic redundancy codes based on the read data; and
by a comparator within the memory manager, comparing the cyclic redundancy codes based on the write data with the cyclic redundancy codes based on the read data, and determining that there is an abnormality if a comparison result is inconsistent.

9. The memory diagnostic method according to claim 8, wherein the memory manager calculates seeds that are increased or reduced by a predetermined amount every time the write data is written or the read data is read, and the cyclic redundancy code calculator adds the calculated seeds to the write data or read data and thereby obtains a different cyclic redundancy code from the same write data or read data.

10. The memory diagnostic method according to claim 8, wherein the write data comprises a plurality of the diagnostic data items.
